(19) United States
(12) Patent Application Publication
(10) Pub. No.: US 2026/0113927 A1
(43) Pub. Date: Apr. 23, 2026

(54) SEMICONDUCTOR STRUCTURE AND MANUFACTURING METHOD THEREOF

(71) Applicant: Winbond Electronics Corp., Taichung City (TW)

(72) Inventors: Po-Han Wu, Pintung (TW); Hao-Chuan Chang, Kaohsiung City (TW); Yuan-Hao Su, Tainan City (TW); Shu-Ming Li, Kaohsiung City (TW)

(73) Assignee: Winbond Electronics Corp., Taichung City (TW)

(21) Appl. No.: 19/359,689

(22) Filed: Oct. 16, 2025

(30) Foreign Application Priority Data
Oct. 21, 2024 (TW) 113139993

(51) Int. Cl. H10B 12/00

(52) U.S. Cl. CPC H10B 12/34; H10B 12/053

(57) ABSTRACT

A semiconductor structure including a substrate, a buried word line structure, and a dielectric barrier layer is provided. The buried word line structure is located in the substrate. The buried word line structure includes a buried word line and a gate dielectric layer. The buried word line is located in the substrate. The gate dielectric layer is located between the buried word line and the substrate. The dielectric barrier layer is located in the substrate above the buried word line structure. The width of the dielectric barrier layer located in the substrate is greater than the width of the buried word line structure. There are air gaps in the dielectric barrier layer adjacent to the substrate.

### CROSS-REFERENCE TO RELATED APPLICATION

This application claims the priority benefit of Taiwan application serial no. 113139993, filed on Oct. 21, 2024. The entirety of the above-mentioned patent application is hereby incorporated by reference herein and made a part of this specification.

### BACKGROUND

### Technical Field

The invention relates to a semiconductor structure and a manufacturing method thereof, and particularly relates to a semiconductor structure having an air gap and a manufacturing method thereof.

### Description of Related Art

Currently, some semiconductor devices (e.g., dynamic random access memory (DRAM) device) have a buried word line located in a substrate. However, how to prevent the leakage current induced by the buried word line and reduce the parasitic capacitance between the buried word line and other components is the goal of continuous efforts.

### SUMMARY

The invention provides a semiconductor structure and a manufacturing method thereof, which can effectively prevent the leakage current and reduce the parasitic capacitance.

The invention provides a semiconductor structure, which includes a substrate, a buried word line structure, and a dielectric barrier layer. The buried word line structure is located in the substrate. The buried word line structure includes a buried word line and a gate dielectric layer. The buried word line is located in the substrate. The gate dielectric layer is located between the buried word line and the substrate. The dielectric barrier layer is located in the substrate above the buried word line structure. The width of the dielectric barrier layer located in the substrate is greater than the width of the buried word line structure. There are air gaps in the dielectric barrier layer adjacent to the substrate.

The invention provides a manufacturing method of a semiconductor structure, which includes the following steps. A substrate is provided. A buried word line structure is formed in the substrate. The buried word line structure includes a buried word line and a gate dielectric layer. The buried word line is located in the substrate. The gate dielectric layer is located between the buried word line and the substrate. A dielectric barrier layer is formed in the substrate above the buried word line structure. The width of the dielectric barrier layer located in the substrate is greater than the width of the buried word line structure. There are air gaps in the dielectric barrier layer adjacent to the substrate.

Based on the above description, in the semiconductor structure and the manufacturing method thereof according to the invention, since the width of the dielectric barrier layer located in the substrate is greater than the width of the buried word line structure, the leakage current (e.g., gate induced drain leakage (GIDL)) can be effectively prevented. In addition, since there are air gaps in the dielectric barrier layer adjacent to the substrate, the parasitic capacitance between the buried word line and the doped region (e.g., source region and/or drain region) subsequently formed in the substrate can be effectively reduced.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1J are cross-sectional views of a manufacturing process of a semiconductor structure according to some embodiments of the invention.

FIG. 2A to FIG. 2J are cross-sectional views of a manufacturing process of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

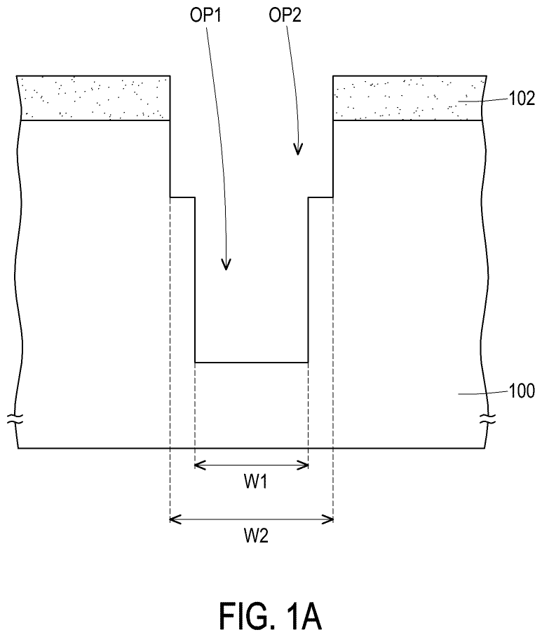

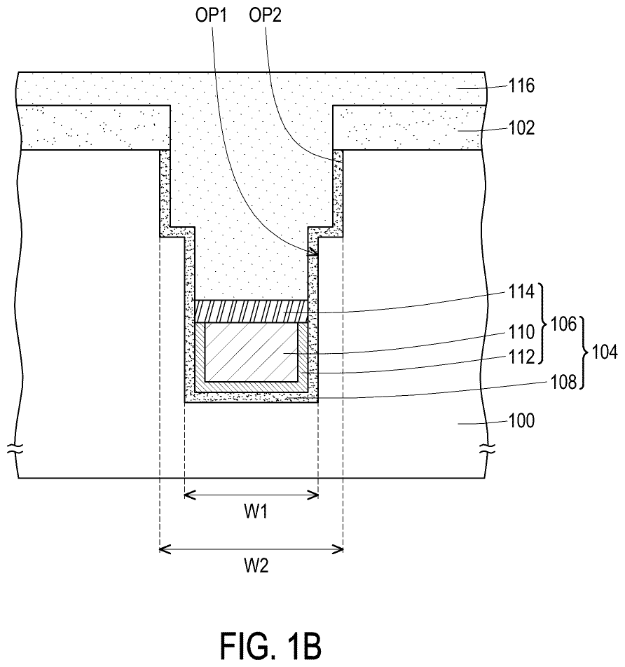

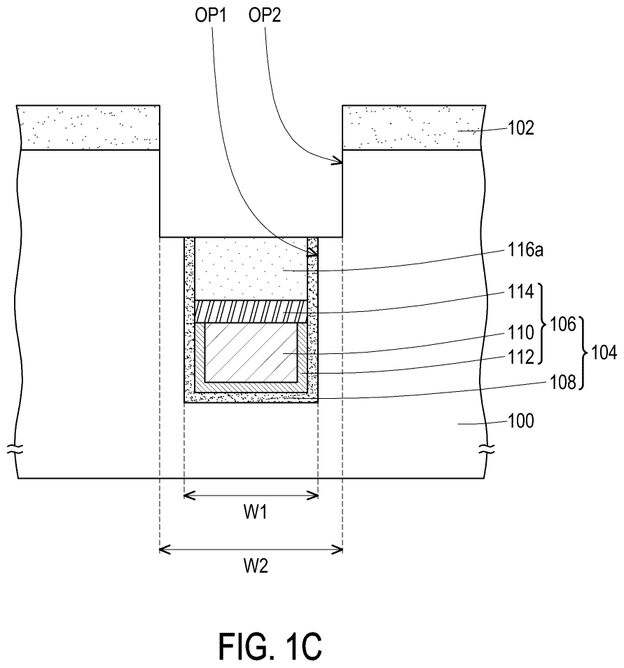

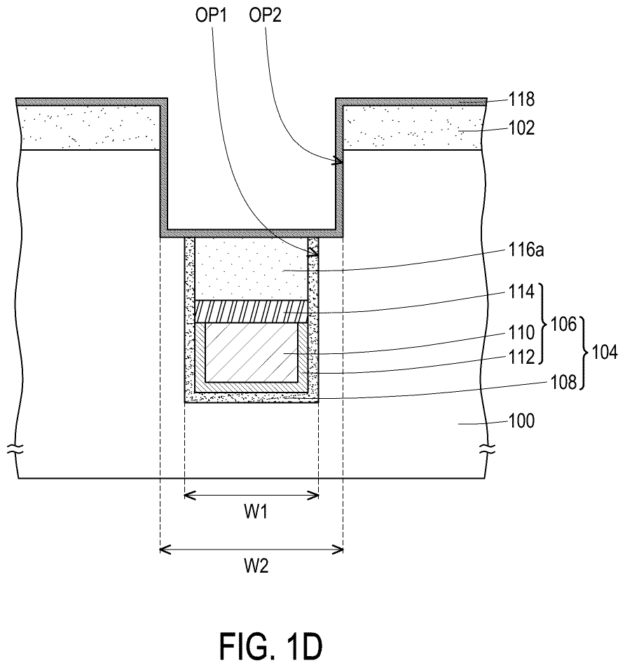

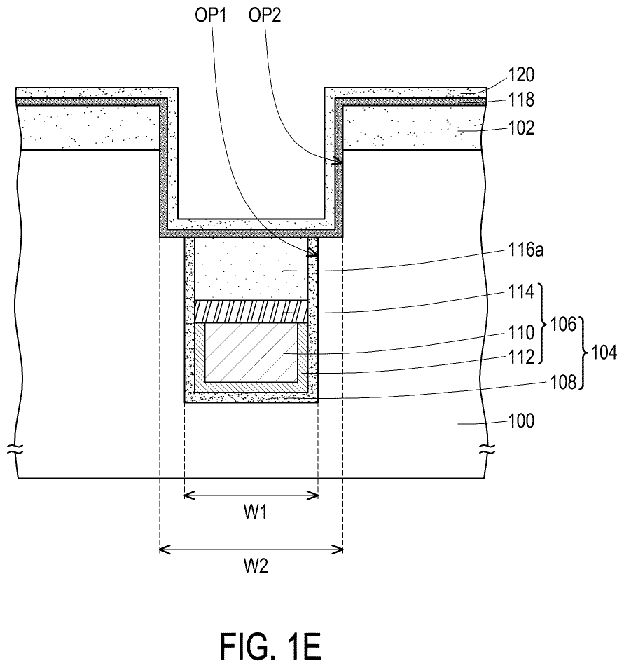

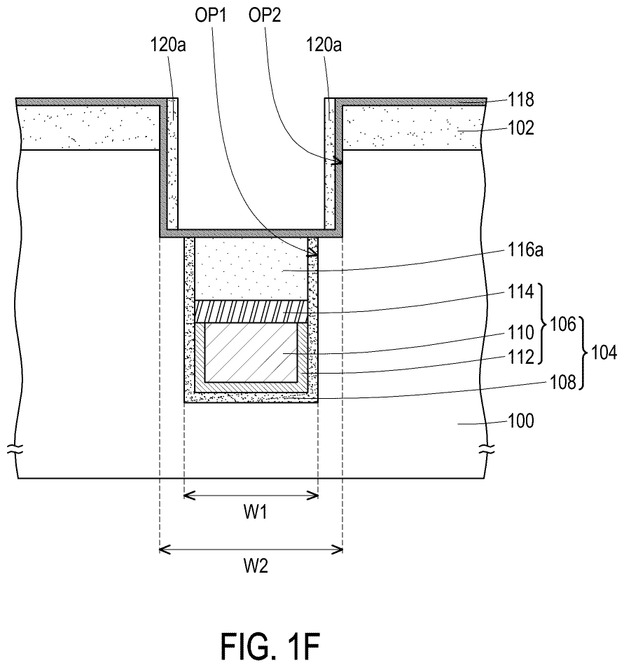

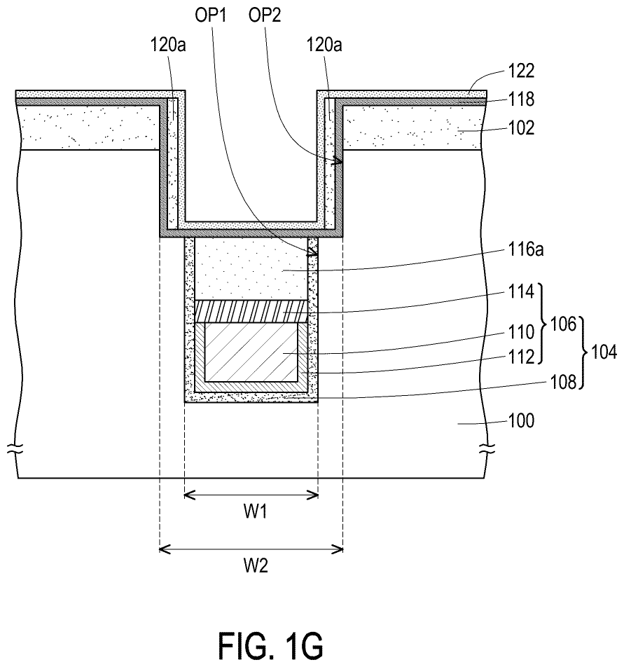

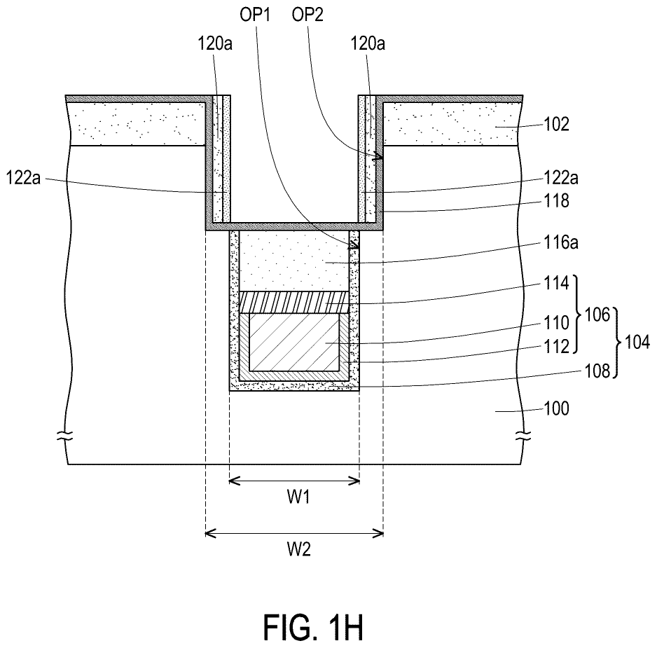

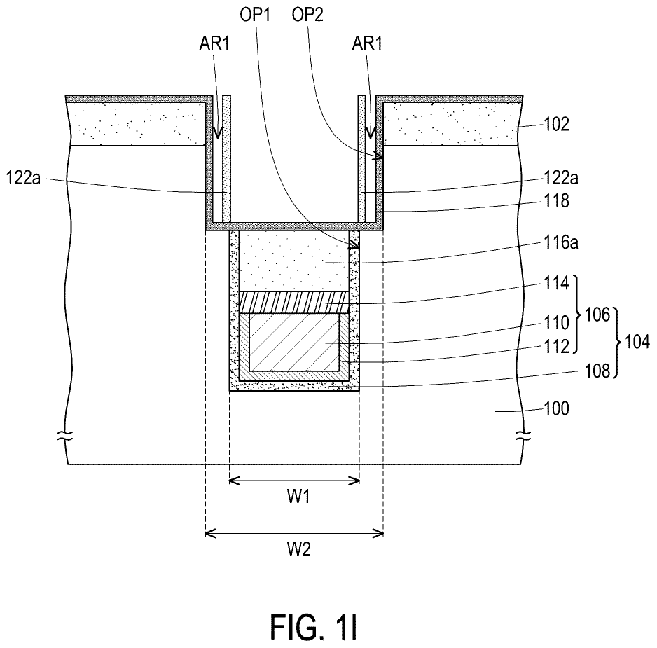

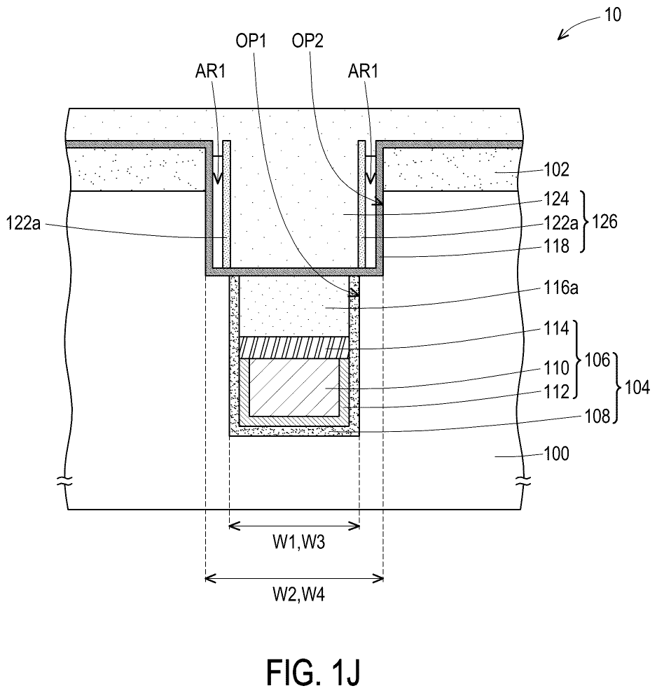

FIG. 1A to FIG. 1J are cross-sectional views of a manufacturing process of a semiconductor structure according to some embodiments of the invention.

Referring to FIG. 1A, a substrate 100 is provided. The substrate 100 may be a semiconductor substrate such as silicon substrate. An opening OP1 may be formed in the substrate 100. The opening OP1 may be formed by performing a self-aligned double patterning (SADP) process or a lithography etching process on the substrate 100. An opening OP2 may be formed in the substrate 100 above the opening OP1, where the width W2 of the opening OP2 is greater than the width W1 of the opening OP1. The opening OP2 may be formed by performing a SADP process or a lithography etching process on the substrate 100. In addition, in the process of forming the opening OP1 and the opening OP2, a mask layer 102 may be formed. The material of the mask layer 102 is, for example, oxide (e.g., silicon oxide).

Referring to FIG. 1B, a buried word line structure 104 may be formed in the opening OP1. Therefore, the buried word line structure 104 may be formed in the substrate 100. The buried word line structure 104 includes a buried word line 106 and a gate dielectric layer 108. The buried word line 106 is located in the substrate 100. The gate dielectric layer 108 is located between the buried word line 106 and the substrate 100. The material of the gate dielectric layer 108 is, for example, oxide (e.g., silicon oxide). The method of forming the gate dielectric layer 108 may include a thermal oxidation method. The buried word line 106 may include a conductive layer 110, a barrier layer 112, and a conductive layer 114. The material of the conductive layer 110 is, for example, metal (e.g., tungsten). The barrier layer 112 is located between the conductive layer 110 and the gate dielectric layer 108. The material of the barrier layer 112 is, for example, titanium, titanium nitride, or a combination thereof. The conductive layer 114 is located on the conductive layer 110 and the barrier layer 112. The gate dielectric layer 108 may further be located between the conductive layer 114 and the substrate 100. The material of the conductive layer 114 is, for example, doped polysilicon.

A capping material layer 116 may be formed in the opening OP1 and the opening OP2. The capping material layer 116 may be further formed on the mask layer 102. The material of the capping material layer 116 is, for example, nitride (e.g., silicon nitride). The method of forming the capping material layer 116 is, for example, a chemical vapor deposition (CVD) method.

Referring to FIG. 1C, an etch back process may be performed on the capping material layer 116 to form a capping layer 116a in the opening OP1. The capping layer 116a may be formed on the buried word line structure 104. The gate dielectric layer 108 may be located between the capping layer 116a and the substrate 100. In the above etch back process, a portion of the mask layer 102 and a portion of the gate dielectric layer 108 may be simultaneously removed. The above etch back process is, for example, a dry etching process.

Referring to FIG. 1D, a dielectric layer 118 may be conformally formed in the opening OP2. The dielectric layer 118 may be further formed on the mask layer 102. The material of the dielectric layer 118 is, for example, nitride (e.g., silicon nitride). The method of forming the dielectric layer 118 is, for example, an atomic layer deposition (ALD) method.

Referring to FIG. 1E, a spacer material layer 120 may be conformally formed on the dielectric layer 118. The material of the spacer material layer 120 is, for example, oxide (e.g., silicon oxide). The method of forming the spacer material layer 120 is formed by, for example, an ALD method.

Referring to FIG. 1F, an etch back process may be formed on the spacer material layer 120 to form spacers 120a on the dielectric layer 118 on two sides of the buried word line structure 104. The above etch back process is, for example, a dry etching process.

Referring to FIG. 1G, a dielectric material layer 122 may be conformally formed on the dielectric layer 118 and the spacers 120a. The material of the dielectric material layer 122 is, for example, nitride (e.g., silicon nitride). The method of forming the dielectric material layer 122 is, for example, an ALD method.

Referring to FIG. 1H, an etch back process may be formed on the dielectric material layer 122 to form dielectric layers 122a and expose the spacers 120a. The above etch back process is, for example, a dry etching process.

Referring to FIG. 1I, the spacers 120a may be removed to form air gaps AR1. The method of removing the spacers 120a is, for example, a wet etching method.

Referring to FIG. 1J, a dielectric layer 124 sealing the top portions of the air gaps AR1 may be formed. The dielectric layer 124 may fill the opening OP2. The material of the dielectric layer 124 is, for example, nitride (e.g., silicon nitride). The method of forming the dielectric layer 124, for example, a CVD method.

By the above method, a dielectric barrier layer 126 may be formed in the substrate 100 above the buried word line structure 104. The dielectric barrier layer 126 may be formed on the capping layer 116a. The dielectric barrier layer 126 may include the dielectric layer 118, the dielectric layers 122a, and the dielectric layer 124.

Hereinafter, a semiconductor structure 10 of the above embodiment is described with reference to FIG. 1J. In addition, although the method of forming the semiconductor structure 10 is described by taking the above method as an example, the invention is not limited thereto.

Referring to FIG. 1J, the semiconductor structure 10 includes a substrate 100, a buried word line structure 104, and a dielectric barrier layer 126. In some embodiments, the semiconductor structure 10 may be used in a DRAM structure. The buried word line structure 104 is located in the substrate 100. The buried word line structure 104 includes a buried word line 106 and a gate dielectric layer 108. The buried word line 106 is located in the substrate 100. The gate dielectric layer 108 is located between the buried word line 106 and the substrate 100. The dielectric barrier layer 126 is located in the substrate 100 above the buried word line structure 104. The width W4 of the dielectric barrier layer 126 located in the substrate 100 is greater than the width W3 of the buried word line structure 104. There are air gaps AR1 in the dielectric barrier layer 126 adjacent to the substrate 100. The air gaps AR1 may be located above two sides of the buried word line structure 104.

The dielectric barrier layer 126 may include a dielectric layer 118, dielectric layers 122a, and a dielectric layer 124. The dielectric layer 118 is located between the air gaps AR1 and the substrate 100. The dielectric layers 122a are located on the dielectric layer 118. The air gaps AR1 are located between the dielectric layer 118 and the dielectric layers 122a. The dielectric layer 124 may seal the top portions of the air gaps AR1. The dielectric layer 124 may fill the air gaps AR1, and the dielectric layer 124 does not completely fill the air gaps AR1. The dielectric layer 124 is located aside the dielectric layers 122a. The dielectric layers 122a are located between the air gaps AR1 and the dielectric layer 124. The dielectric layer 124 is located on the dielectric layer 118 and between the dielectric layers 122a. The material of the dielectric layer 118, the materials of the dielectric layers 122a, and the material of the dielectric layer 124 are, for example, nitride (e.g., silicon nitride).

The semiconductor structure 10 may further include a capping layer 116a. The capping layer 116a is located between the buried word line structure 104 and the dielectric barrier layer 126. The gate dielectric layer 108 may be further located between the capping layer 116a and the substrate 100.

In addition, the remaining components in the semiconductor structure 10 may refer to the description of the above embodiments. Moreover, the details (e.g., materials and formation methods, etc.) of components in the semiconductor structure 10 have been described in detail in the above embodiments, and the description thereof is not repeated here.

Based on the above embodiments, in the semiconductor structure 10 and the manufacturing method thereof, since the width W4 of the dielectric barrier layer 126 located in the substrate 100 is greater than the width W3 of the buried word line structure 104, the leakage current (e.g., GIDL) can be effectively prevented. In addition, since there are air gaps AR1 in the dielectric barrier layer 126 adjacent to the substrate 100, the parasitic capacitance between the buried word line 106 and the doped region (e.g., source region and/or drain region) subsequently formed in the substrate 100 can be effectively reduced.

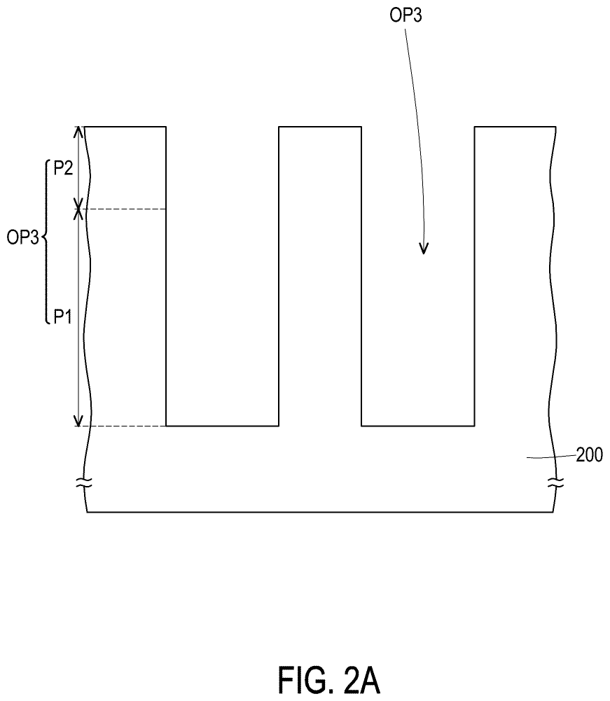

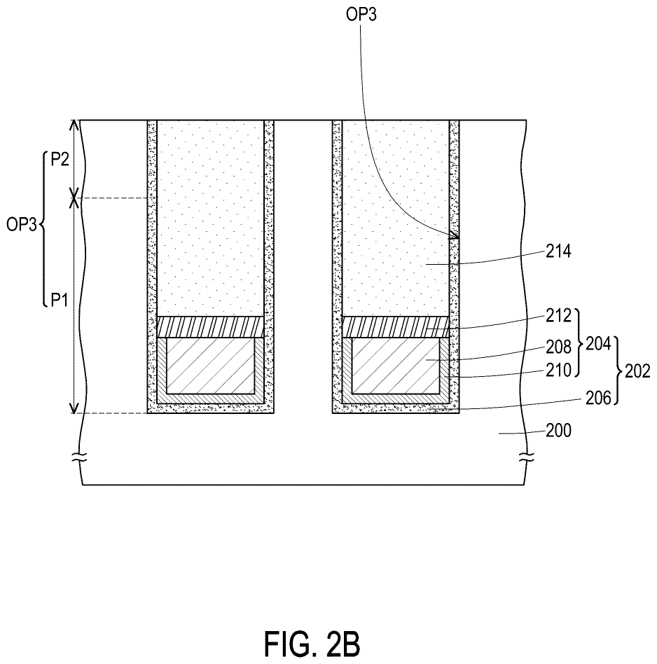

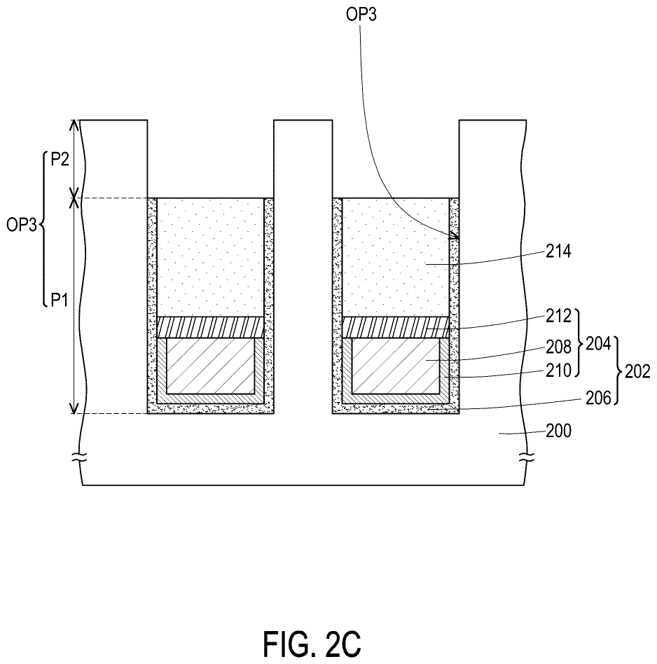

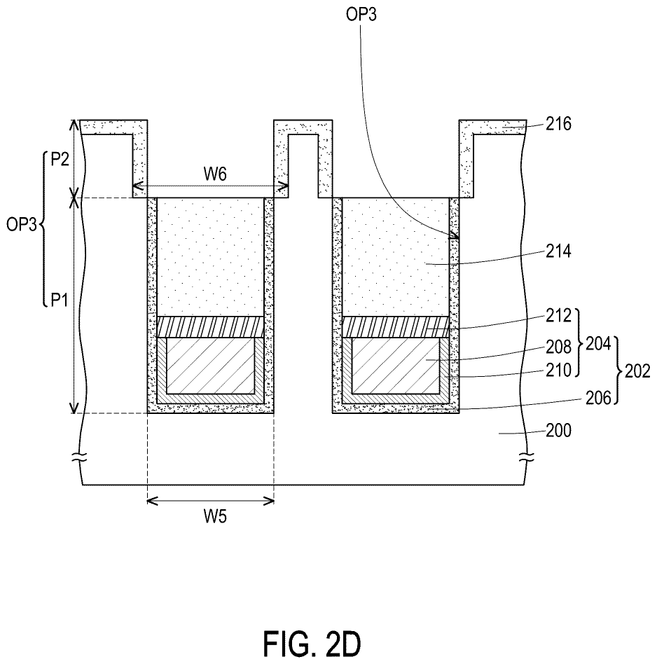

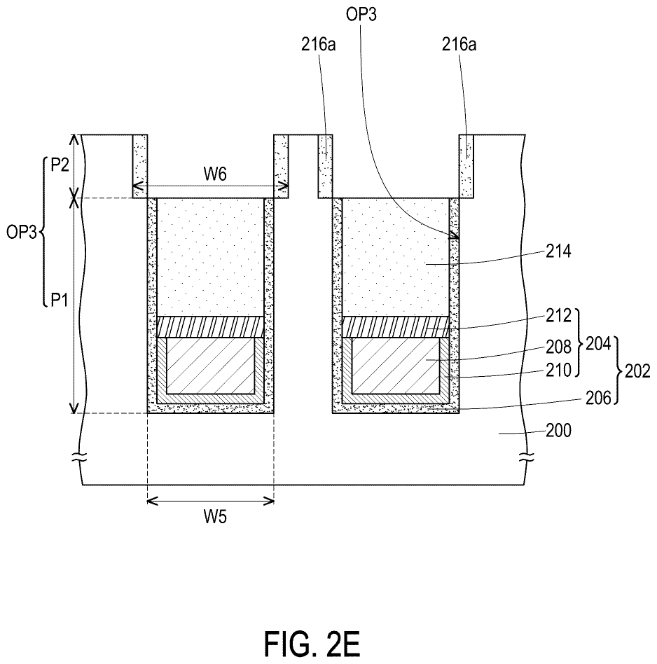

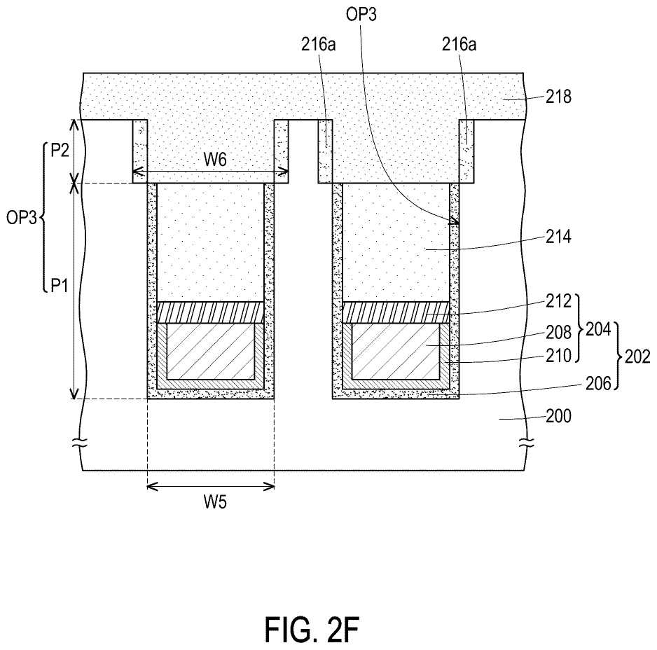

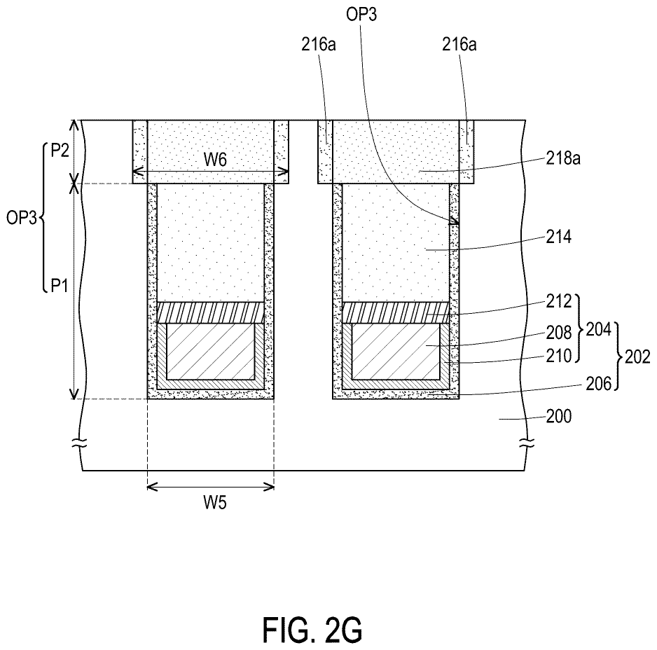

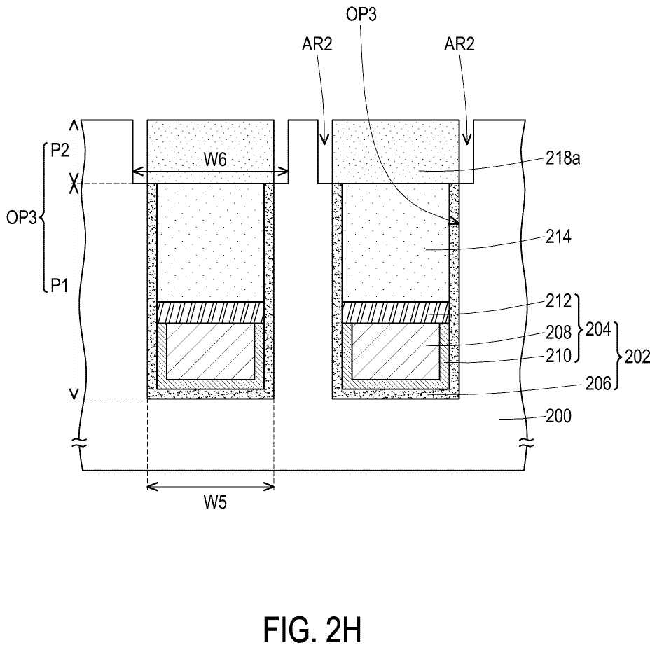

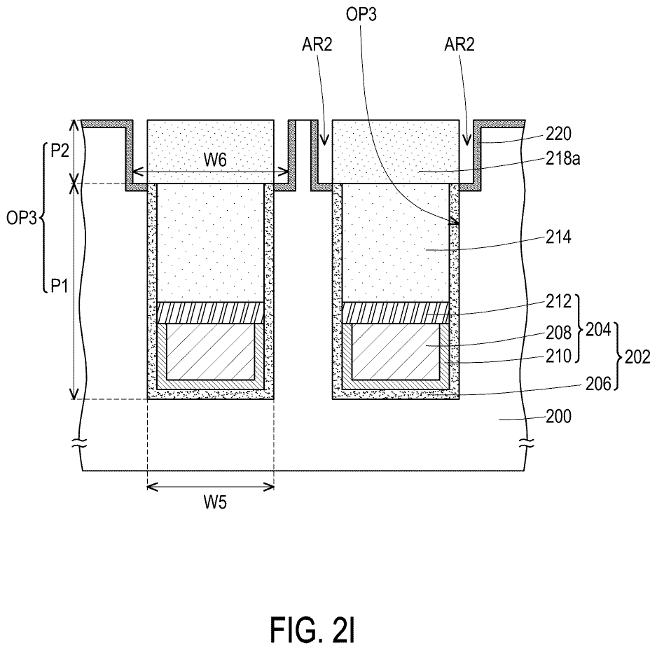

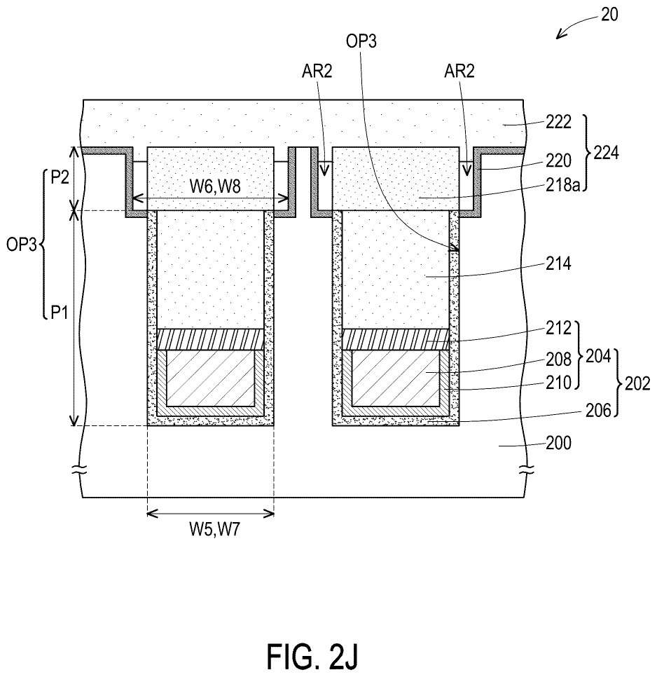

FIG. 2A to FIG. 2J are cross-sectional views of a manufacturing process of a semiconductor structure according to other embodiments of the invention.

Referring to FIG. 2A, a substrate 200 is provided. The substrate 200 may be a semiconductor substrate such as silicon substrate. An opening OP3 may be formed in the substrate 200. The opening OP3 includes a lower portion P1 and an upper portion P2. The opening OP3 may be formed by performing a SADP process or a lithography etching process on the substrate 200.

Referring to FIG. 2B, a buried word line structure 202 may be formed in the lower portion P1 of the opening OP3. Therefore, the buried word line structure 202 may be formed in the substrate 200. The buried word line structure 202 includes a buried word line 204 and a gate dielectric layer 206. The buried word line 204 is located in the substrate 200. The gate dielectric layer 206 is located between the buried word line 204 and the substrate 200. The material of the gate dielectric layer 206 is, for example, oxide (e.g., silicon oxide). The method of forming the gate dielectric layer 206 may include a thermal oxidation method. The buried word line 204 may include a conductive layer 208, a barrier layer 210, and a conductive layer 212. The material of the conductive layer 208 is, for example, metal (e.g., tungsten). The barrier layer 210 is located between the conductive layer 208 and the gate dielectric layer 206. The material of the barrier layer 210 is, for example, titanium, titanium nitride, or a combination thereof. The conductive layer 212 is located on the conductive layer 208 and the barrier layer 210. The gate dielectric layer 206 may be further located between the conductive layer 212 and the substrate 200. The material of the conductive layer 212 is, for example, doped polysilicon.

A capping layer 214 may be formed in the opening OP3. The material of the capping layer 214 is, for example, nitride (e.g., silicon nitride). The method of forming the capping layer 214 may include the following steps. First, a capping material layer (not shown) filling the opening OP3 is formed. Then, the capping material layer located outside the opening OP3 is removed to form the capping layer 214.

Referring to FIG. 2C, an etch back process may be performed on the capping layer 214 to form the capping layer 214 in the lower portion P1 of the opening OP3. The capping layer 214 may be formed on the buried word line structure 202. The gate dielectric layer 206 may be located between the capping layer 214 and the substrate 200. In the above etch back process, a portion of the gate dielectric layer 206 may be simultaneously removed. The above etch back process is, for example, a dry etching process.

Referring to FIG. 2D, a spacer material layer 216 may be formed on the substrate 200 by a thermal oxidation method, so that the width W6 of the upper portion P2 of the opening OP3 is greater than the width W5 of the lower portion P1 of the opening OP3. The material of the spacer material layer 216 is, for example, oxide (e.g., silicon oxide).

Referring to FIG. 2E, an etch back process may be performed on the spacer material layer 216 to form spacers 216a. Therefore, the spacers 216a may be formed on the sidewalls of the upper portion P2 of the opening OP3. The above etch back process is, for example, a dry etching process.

Referring to FIG. 2F, a dielectric material layer 218 may be formed on the substrate 100 and the spacers 216a and in the opening OP3. The material of the dielectric material layer 218 is, for example, nitride (e.g., silicon nitride). The method of forming the dielectric material layer 218 is, for example, a CVD method.

Referring to FIG. 2G, an etch back process may be performed on the dielectric material layer 218 to form a dielectric layer 218a and expose the spacers 216a and the substrate 200. Therefore, the dielectric layer 218a may be formed in the upper portion P2 of the opening OP3. The dielectric layer 218a is located between the spacers 216a. The above etch back process is, for example, a dry etching process.

Referring to FIG. 2H, the spacers 216a may be removed to form air gaps AR2. The method of removing the spacers 216a is, for example, a wet etching method.

Referring to FIG. 2I, dielectric layers 220 may be formed on the substrate 200 exposed by the upper portion P2 of the opening OP3. The dielectric layer 220 may further be formed on the top surface of the substrate 200. The air gaps AR2 are located between the dielectric layer 218a and the dielectric layers 220. The method of forming the dielectric layers 220 are, for example, a thermal oxidation method. The material of the dielectric layer 220 is, for example, oxide (e.g., silicon oxide).

Referring to FIG. 2J, a dielectric layer 222 sealing the top portions of the air gaps AR2 may be formed. The material of the dielectric layer 222 is, for example, nitride (e.g., silicon nitride). The method of forming the dielectric layer 222 is, for example, a CVD method.

By the above method, a dielectric barrier layer 224 may be formed in the substrate 200 above the buried word line structure 202. The dielectric barrier layer 224 may be formed on the capping layer 214. The dielectric barrier layer 224 may include the dielectric layer 218a, the dielectric layers 220, and the dielectric layer 222.

Hereinafter, a semiconductor structure 20 of the above embodiment is described with reference to FIG. 2J. In addition, although the method of forming the semiconductor structure 10 is described by taking the above method as an example, the invention is not limited thereto.

Referring to FIG. 2J, the semiconductor structure 20 includes a substrate 200, a buried word line structure 202, and a dielectric barrier layer 224. In some embodiments, the semiconductor structure 20 may be used in a DRAM structure. The buried word line structure 202 is located in the substrate 200. The buried word line structure 202 includes a buried word line 204 and a gate dielectric layer 206. The buried word line 204 is located in the substrate 200. The gate dielectric layer 206 is located between the buried word line 204 and the substrate 200. The dielectric barrier layer 224 is located in the substrate 200 above the buried word line structure 202. The width W8 of the dielectric barrier layer 224 located in the substrate 200 is greater than the width W7 of the buried word line structure 202. There are air gaps AR2 in the dielectric barrier layer 224 adjacent to the substrate 200. The air gaps AR2 may be located above two sides of the buried word line structure 202.

The dielectric barrier layer 224 may include a dielectric layer 218a, dielectric layers 220, and a dielectric layer 222. The dielectric layer 218a is located in the substrate 200. The dielectric layers 220 are located between the sidewalls of the dielectric layer 218a and the substrate 200. The air gaps AR2 are located between the dielectric layer 218a and the dielectric layers 220. The dielectric layer 222 may seal the top portions of the air gaps AR2.

The dielectric layer 222 may fill the air gaps AR2, and the dielectric layer 222 does not completely fill the air gaps AR2. The dielectric layer 222 may be located on the dielectric layer 218a and the dielectric layer 220. The material of the dielectric layer 218a and the material of the dielectric layer 222 include nitride (e.g., silicon nitride), and the materials of the dielectric layers 220 include oxides (e.g., silicon oxide).

The semiconductor structure 20 may further include a capping layer 214. The capping layer 214 is located between the buried word line structure 202 and the dielectric barrier layer 224. The gate dielectric layer 206 may be further located between the capping layer 214 and the substrate 200.

In addition, the remaining components in the semiconductor structure 20 may refer to the description of the above embodiments. Moreover, the details (e.g., materials and formation methods, etc.) of components in the semiconductor structure 20 have been described in detail in the above embodiments, and the description thereof is not repeated here.

Based on the above embodiments, in the semiconductor structure 20 and the manufacturing method thereof, since the width W8 of the dielectric barrier layer 224 located in the substrate 200 is greater than the width W7 of the buried word line structure 202, the leakage current (e.g., GIDL) can be effectively prevented. In addition, since there are air gaps AR2 in the dielectric barrier layer 224 adjacent to the substrate 200, the parasitic capacitance between the buried word line 204 and the doped region (e.g., source region and/or drain region) subsequently formed in the substrate 200 can be effectively reduced.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate;
a buried word line structure located in the substrate and comprising:
a buried word line located in the substrate; and
a gate dielectric layer located between the buried word line and the substrate; and
a dielectric barrier layer located in the substrate above the buried word line structure, wherein
a width of the dielectric barrier layer located in the substrate is greater than a width of the buried word line structure, and
there are air gaps in the dielectric barrier layer adjacent to the substrate.

2. The semiconductor structure according to claim 1, wherein the air gaps are located above two sides of the buried word line structure.

3. The semiconductor structure according to claim 1, wherein the dielectric barrier layer comprises:
a first dielectric layer located between the air gaps and the substrate;
second dielectric layers located on the first dielectric layer, wherein the air gaps are located between the first dielectric layer and the second dielectric layers; and
a third dielectric layer sealing top portions of the air gaps.

4. The semiconductor structure according to claim 3, wherein the third dielectric layer fills the air gaps, and the third dielectric layer does not completely fill the air gaps.

5. The semiconductor structure according to claim 3, wherein the third dielectric layer is located aside to the second dielectric layers, and the second dielectric layers are located between the air gaps and the third dielectric layer.

6. The semiconductor structure according to claim 3, wherein the third dielectric layer is located on the first dielectric layer and between the second dielectric layers.

7. The semiconductor structure according to claim 3, wherein a material of the first dielectric layer, materials of the second dielectric layers, and a material of the third dielectric layer comprise nitride.

8. The semiconductor structure according to claim 1, wherein the dielectric barrier layer comprises:
a first dielectric layer located in the substrate;
second dielectric layers located between sidewalls of the first dielectric layer and the substrate, wherein the air gaps are located between the first dielectric layer and the second dielectric layers; and
a third dielectric layer sealing top portions of the air gaps.

9. The semiconductor structure according to claim 8, wherein the third dielectric layer fills the air gaps, and the third dielectric layer does not completely fill the air gaps.

10. The semiconductor structure according to claim 8, wherein a material of the first dielectric layer and a material of the third dielectric layer comprise nitride, and materials of the second dielectric layers comprise oxide.

11. The semiconductor structure according to claim 1, further comprising:
a capping layer located between the buried word line structure and the dielectric barrier layer.

12. The semiconductor structure according to claim 11, wherein the gate dielectric layer is further located between the capping layer and the substrate.

13. The semiconductor structure according to claim 12, wherein the buried word line comprises:
a first conductive layer;
a barrier layer located between the first conductive layer and the gate dielectric layer; and
a second conductive layer located on the first conductive layer and the barrier layer, wherein the gate dielectric layer is further located between the second conductive layer and the substrate.

14. A manufacturing method of a semiconductor structure, comprising:
providing a substrate;
forming a buried word line structure in the substrate, wherein the buried word line structure comprises:
a buried word line located in the substrate; and
a gate dielectric layer located between the buried word line and the substrate; and
forming a dielectric barrier layer in the substrate above the buried word line structure, wherein
a width of the dielectric barrier layer located in the substrate is greater than a width of the buried word line structure, and
there are air gaps in the dielectric barrier layer adjacent to the substrate.

15. The manufacturing method of the semiconductor structure according to claim 14, wherein a method of forming the buried word line structure and the dielectric barrier layer comprises:
forming a first opening in the substrate;
forming a second opening in the substrate above the first opening, wherein a width of the second opening is greater than a width of the first opening;
forming the buried word line structure in the first opening;
conformally forming a first dielectric layer in the second opening;
forming spacers on the first dielectric layer on two sides of the buried word line structure;
conformally forming a dielectric material layer on the first dielectric layer and the spacers;
performing an etch back process on the dielectric material layer to form second dielectric layers and expose the spacers;
removing the spacers to form the air gaps; and
forming a third dielectric layer sealing top portions of the air gaps, wherein
the dielectric barrier layer comprises the first dielectric layer, the second dielectric layers, and the third dielectric layer.

16. The manufacturing method of the semiconductor structure according to claim 15, further comprising:
forming a capping layer in the first opening, wherein the capping layer is formed on the buried word line structure, and the dielectric barrier layer is formed on the capping layer.

17. The manufacturing method of the semiconductor structure according to claim 14, wherein a method of forming the buried word line structure and the dielectric barrier layer comprises:
forming an opening in the substrate, wherein the opening comprises a lower portion and an upper portion;
forming the buried word line structure in the lower portion of the opening;
forming spacers on sidewalls of the upper portion of the opening;
forming a first dielectric layer in the upper portion of the opening, wherein the first dielectric layer is located between the spacers;
removing the spacers to form the air gaps;
forming second dielectric layers on the substrate exposed by the upper portion of the opening, wherein the air gaps are located between the first dielectric layer and the second dielectric layers;
forming a third dielectric layer sealing top portions of the air gaps, wherein
the dielectric barrier layer comprises the first dielectric layer, the second dielectric layers, and the third dielectric layer.

18. The manufacturing method of the semiconductor structure according to claim 17, wherein a method of forming the spacers comprises:
forming a spacer material layer on the substrate by a thermal oxidation method, so that a width of the upper portion of the opening is greater than a width of the lower portion of the opening; and
performing an etch back process on the spacer material layer to form the spacers.

19. The manufacturing method of the semiconductor structure according to claim 17, wherein a method of forming the second dielectric layers comprises a thermal oxidation method.

20. The manufacturing method of the semiconductor structure according to claim 17, further comprising:
forming a capping layer in the lower portion of the opening, wherein the capping layer is formed on the buried word line structure, and the dielectric barrier layer is formed on the capping layer.
